(19) United States
(12) Patent Application Publication
(10) Pub. No.: US 2023/0402525 A1
(43) Pub. Date: Dec. 14, 2023

(54) MANUFACTURING METHOD FOR N-POLAR GAN TRANSISTOR STRUCTURE AND SEMICONDUCTOR STRUCTURE

(71) Applicant: Institute of Semiconductors, Guangdong Academy of Sciences, Guangzhou, Guangdong (CN)

(72) Inventors: Chengguo LI, Guangzhou, Guangdong (CN); Qiaoyu ZENG, Guangzhou, Guangdong (CN); Xuebing YIN, Guangzhou, Guangdong (CN); Xiaoming GE, Guangzhou, Guangdong (CN); Zhitao CHEN, Guangzhou, Guangdong (CN)

(73) Assignee: Institute of Semiconductors, Guangdong Academy of Sciences, Guangzhou, Guangdong (CN)

(21) Appl. No.: 18/035,663

(22) PCT Filed: Dec. 27, 2021
(86) PCT No.: PCT/CN2021/141765

§ 371 Date: May 5, 2023

(30) Foreign Application Priority Data
Jul. 1, 2021 (CN) 202110742866.X

(51) Int. Cl. H01L 29/66; H01L 29/20; H01L 29/06; H01L 29/778

(52) U.S. Cl. CPC H01L 29/66462; H01L 29/2003; H01L 29/0603; H01L 29/7786

(57) ABSTRACT

Embodiments of the present application relate to the technical field of semiconductors, and provide a manufacturing method for an N-polar GaN transistor structure and a semiconductor structure. A Ga-polar epitaxial functional layer is formed by depositing, a supporting substrate is formed on the epitaxial functional layer by bonding, after the epitaxial structure is inverted, a structural substrate and a buffer layer are removed, and a source, a drain, and a gate are manufactured on the side of the exposed epitaxial functional layer away from the supporting substrate, to form an N-polar GaN transistor structure.

### CROSS-REFERENCE TO RELATED APPLICATIONS

The present application claims priority to PCT Application No. PCT/CN2021/141765, filed on Dec. 27, 2021, which claims priority to Chinese Patent Application No. CN 202110742866.X, filed on Jul. 1, 2021, the contents of which are incorporated herein by reference in their entireties.

### TECHNICAL FIELD

The present application relates to the field of GaN-based electronic devices, and particularly to a fabrication method (i.e., a manufacturing method) of an N-polar GaN transistor structure and a semiconductor structure.

### BACKGROUND ART

Polarity is one of the important properties of III-nitride semiconductor materials. Traditional GaN-based electronic and optoelectronic devices are based on Ga-polar materials. However, an electronic device based on an N-polar GaN material may have benefits owing to the opposite polarization field to that of the traditional Ga-polar materials. These benefits include but are not limited to lower contact resistance, higher high-voltage resistance, higher power density, and higher flexibility in device design. In recent years, N-polar Ga(Al)N transistors have gradually attracted great interest in academia and industry due to their excellent performance in the fields of power switches and radio frequency (RF) amplifiers. In the field of power-switches, N-polar high electron mobility transistors (HEMTs) have demonstrated ultra-low dynamic on-resistance (˜5%) and high breakdown voltage (>2000 V); and in the field RF amplifiers, N-polar HEMT devices have achieved ultra-high power density (8 W/mm) and power added efficiency (27.8%) at a frequency of 94 GHz, and is far superior to any current similar Ga-polar device.

The preparation of high-quality N-polar GaN materials is a great challenge. Currently, most N-polar GaN materials are obtained by directly growing on sapphire or SiC substrates by metal-organic vapor phase epitaxy (MOVPE) or molecular beam epitaxy (MBE). The resulting material usually has a high surface roughness, poor crystal quality, and a high impurity concentration. An N-polar HEMT with a sharp GaN/AlGaN hetero-interface and a high-resistance N-polar GaN insulating layer is difficult to obtain, leading to high channel resistance and large off-state current leakage.

### SUMMARY

The present application provides a fabrication method of an N-polar GaN transistor structure and a semiconductor structure, which may obtain an N-polar GaN HEMT with a high-resistance GaN insulating layer and a steep-interface heterojunction, thus improving the device performance.

Some embodiments of the present application provide a fabrication method of an N-polar GaN transistor structure, which may include: forming a buffer layer by depositing on one side of a structural substrate; forming an etching-blocking barrier layer by depositing on a side of the buffer layer away from the structural substrate; forming an epitaxial functional layer of an upside-down (inverted)N-polar transistor by depositing on a side of the etching-blocking barrier layer away from the structural substrate, such that a side of the epitaxial functional layer away from the structural substrate is a Ga-polar surface; forming a support substrate by bonding on a side of the epitaxial functional layer away from the structural substrate; removing the structural substrate to make the buffer layer exposed; removing the buffer layer to make the etching-blocking barrier layer exposed; and manufacturing a source electrode, a drain electrode, and a gate electrode on a side of the epitaxial functional layer away from the support substrate to form an N-polar GaN transistor.

In an optional embodiment, after the step of removing the buffer layer to make the etching-blocking barrier layer exposed, the fabrication method may further include: removing the etching-blocking barrier layer to make the epitaxial functional layer exposed.

In an optional embodiment, the step of forming an epitaxial functional layer of an upside-down N-polar transistor by depositing on a side of the etching-blocking barrier layer away from the structural substrate may include: forming a Ga-polar channel layer by depositing on the etching-blocking barrier layer; forming a Ga-polar barrier layer by depositing on the channel layer; forming a Ga-polar isolation layer by depositing on the barrier layer; and forming a Ga-polar insulating layer by depositing on the isolation layer.

In an optional embodiment, the channel layer may be made of at least one of GaN, AlN, InAlN, AlGaN, and InAlGaN; and the barrier layer may be made of at least one of AlN, InAlN, AlGaN, InAlGaN, and AlScN. A energy bandgap of the barrier layer is greater than that of the channel layer, and a two-dimensional electron gas with a high concentration and high electron mobility is formed on an interface, at a side close to the channel layer, between the barrier layer and the channel layer.

In an optional embodiment, after the step of forming an insulating layer by depositing on the isolation layer, the fabrication method may further include: forming a p-type doped layer by depositing on the insulating layer.

In an optional embodiment, the p-type doped layer is made of a p-GaN material.

In an optional embodiment, the step of forming a support substrate by bonding on a side of the epitaxial functional layer away from the structural substrate may include: forming a bonding layer by depositing on the epitaxial functional layer; and forming the support substrate by bonding on the bonding layer.

In an optional embodiment, the bonding layer may be formed by depositing on a surface of a side of the p-type doped layer away from the structural substrate, and the epitaxial functional layer and the support substrate may be bonded by a method of direct bonding or adhesive bonding.

In an optional embodiment, the etching-blocking barrier layer may be made of AlₓGa₁₋ₓN, wherein x is a fraction of Al, and 0<x≤1; and the fraction of Al in the etching-blocking barrier layer is higher than that in the channel layer.

In an optional embodiment, the etching-blocking barrier layer may have a thickness of at least 1 nm.

Other embodiments of the present application provide a semiconductor structure, manufactured using the fabrication method of the N-polar GaN transistor structure according to any of the foregoing embodiments, which may include: an etching-blocking barrier layer; an epitaxial functional layer, located on one side of the etching-blocking barrier layer, wherein a side of the epitaxial functional layer close to the etching-blocking barrier layer is an N-polar surface, and a side of the epitaxial functional layer away from the etching-blocking barrier layer is a Ga-polar surface; a support substrate, located on the Ga-polar surface of the epitaxial functional layer; and a source electrode, a drain electrode, and a gate electrode, located on the N-polar surface of the epitaxial functional layer, wherein the epitaxial functional layer includes a channel layer deposited on the etching-blocking barrier layer, a barrier layer deposited on the channel layer, an isolation layer deposited on the barrier layer, and an insulating layer deposited on the isolation layer.

In an optional embodiment, the epitaxial functional layer may further include a p-type doped layer located on the insulating layer.

In an optional embodiment, the p-type doped layer is bonded to the support substrate, wherein a bonding layer is formed between the p-type doped layer and the support substrate.

In an optional embodiment, regions of the etching-blocking barrier layer on both sides of the gate electrode are removed partially or completely.

In an optional embodiment, the gate electrode is manufactured on the etching-blocking barrier layer, and the source electrode and the drain electrode are manufactured on the channel layer on both sides of the gate electrode.

The embodiments of the present application may at least have, for example, the following beneficial effects.

In the fabrication method of an N-polar GaN transistor structure according to the embodiments of the present application, the Ga-polar epitaxial functional layer is deposited, the support substrate is bonded to the epitaxial functional layer, then the structural substrate and the buffer layer are removed after an epitaxial structure is inverted, and the source electrode, the drain electrode, and the gate electrode are manufactured on the side of the exposed epitaxial functional layer away from the support substrate, to form the N-polar GaN transistor. Herein, the epitaxial structure of the N-polar GaN transistor is obtained by vertically inverting the directly grown Ga-polar epitaxial layer, and has a higher material quality than an N-polar material which is directly grown epitaxially, such that the high-resistance GaN insulating layer and the steep-interface heterojunction may be obtained, thus improving a high-voltage resistance of the N-polar GaN transistor, and reducing a conduction loss of the device. Compared with related art, in the present application, the adoption of the method in which the Ga-polar epitaxial structure is grown firstly, the bonding is then performed, and the substrate and the buffer layer are removed, may solve the problem that the N-polar GaN transistor structure which is directly grown epitaxially has a poor material quality, thus improving the overall performance of the N-polar transistor.

### BRIEF DESCRIPTION OF DRAWINGS

To describe the technical solutions in the embodiments of the present application more clearly, the following briefly describes the accompanying drawings required in the embodiments. It should be understood that the following accompanying drawings show merely some embodiments of the present application and therefore should not be considered as limiting the scope, and a person of ordinary skill in the art may still derive other related drawings from these accompanying drawings without creative efforts.

FIG. 1 is a block diagram of steps of a fabrication method of an N-polar GaN transistor structure according to an embodiment of the present application;

FIGS. 2 to 6 are process flow charts of the fabrication method of an N-polar GaN transistor structure according to the embodiment of the present application;

FIG. 7 is a schematic structural diagram of a semiconductor structure according to an embodiment of the present application;

FIG. 8 is a schematic structural diagram of an enhanced semiconductor structure according to an embodiment of the present application; and

FIG. 9 is a schematic diagram of an integrated structure of the semiconductor structure according to the embodiment of the present application and other devices.

Reference numeral: 100—semiconductor structure; 110—support substrate; 111—bonding layer; 130—epitaxial functional layer; 131—channel layer; 133—barrier layer; 135—isolation layer; 137—insulating layer; 139—p-type doped layer; 150—etching-blocking barrier layer; 160a—source electrode; 160b—drain electrode; 160c—gate electrode; 170—buffer layer; 180—structural substrate.

### DETAILED DESCRIPTION OF EMBODIMENTS

To make the objectives, technical solutions, and advantages of the embodiments of the present application clearer, the technical solutions in the embodiments of the present application are clearly and completely described with reference to the accompanying drawings in the embodiments of the present application, and apparently, the described embodiments are not all but a part of the embodiments of the present application. Generally, the components of the embodiments of the present application described and illustrated in the drawings herein may be arranged and designed in a variety of different configurations.

Accordingly, the following detailed description of the embodiments of the present application provided in the drawings is not intended to limit the scope of protection of the present application, but only represents selected embodiments of the present application. All other embodiments obtained by a person of ordinary skill in the art based on the embodiments of the present application without creative efforts shall fall within the protection scope of the present application.

It should be noted that similar reference signs and letters denote similar items in the following drawings. Therefore, once a certain item is defined in one figure, it does not need to be further defined and explained in the subsequent figures.

In descriptions of the present application, it should be noted that, directions or positional relationships indicated by terms “upper”, “lower”, “inner”, “outer”, etc. are based on orientations or positional relationships shown in the accompanying drawings, or orientations or positional relationships of conventional placement of the product according to the present application in use, and they are used only for describing the present application and for description simplicity, but do not indicate or imply that an indicated device or element must have a specific orientation or be constructed and operated in a specific orientation. Therefore, it cannot be understood as a limitation on the present application.

In addition, the terms such as “first”, “second”, or the like, are only used for distinguishing descriptions and are not intended to indicate or imply relative importance.

As disclosed in the background art, the electronic device based on the N-polar material may have a lower contact resistance, a higher high-voltage resistance, a higher power density and efficiency, a more flexible structural design advantage, and a size shrinkage advantage thanks to the polarization electric field opposite to that of the traditional Ga-polar material. A directly grown Ga-polar GaN material has a good comprehensive quality, and is usually superior to the directly grown N-polar GaN material; that is, the GaN material obtained by Ga-polar growth has a low surface roughness, a good crystal quality, a low impurity concentration, and a low background electron concentration.

In the related art, the N-polar GaN material is usually obtained by directly growing on the sapphire or SiC substrate using the metal-organic vapor phase epitaxy or molecular beam epitaxy method, the GaN material obtained using this method has a high surface roughness, a poor crystal quality, a high impurity concentration, and a high background electron concentration, and the high-resistance insulating layer and the steep heterojunction interface required by the N-polar high electron mobility transistor are difficult to manufacture, such that advantages of the N-polar GaN material are difficult to fully develop in device applications.

In order to solve the above-mentioned problems, the present application provides a fabrication method of an N-polar GaN transistor structure and a semiconductor structure, which may obtain the N-polar GaN high electron mobility transistor with a high-resistance GaN insulating layer and a steep-interface heterojunction, thus improving the device performance. It should be noted that features in embodiments of the present application may be combined with each other without conflicts.

### Embodiment

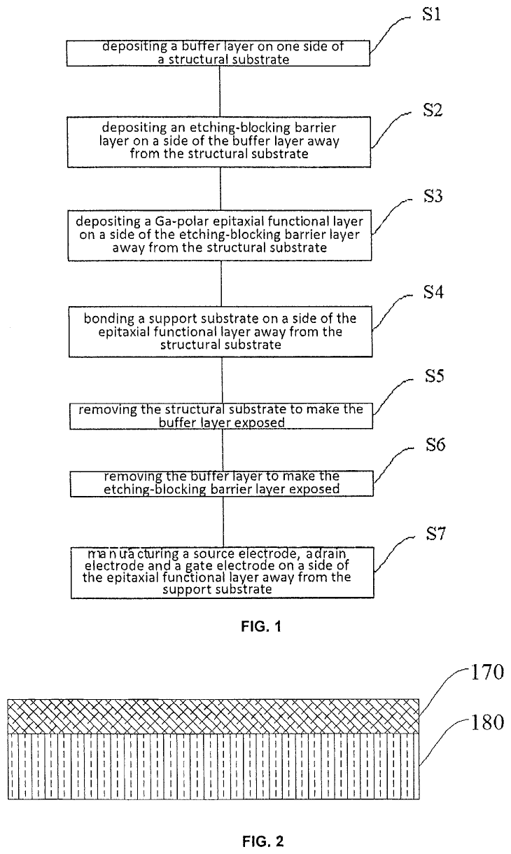

Referring to FIG. 1, the present embodiment provides a fabrication method of an N-polar GaN transistor structure, in which a Ga-polar epitaxial structure is grown first, a bonding is then performed, and a substrate and a buffer layer 170 are removed, so as to obtain an inverted N-polar device, and an N-polar semiconductor device has a better material quality.

The fabrication method of an N-polar GaN transistor structure according to the present embodiment is used to manufacture a semiconductor structure 100, and the semiconductor structure 100 is suitable for an N-polar GaN-based high electron mobility transistor (HEMT) device. Here, the semiconductor structure 100 may be an enhanced N-polar GaN-based HEMT structure or a depletion N-polar GaN-based HEMT structure. For a structure of the HEMT device fabricated based on the semiconductor structure 100, reference may be made to a structure of a HEMT device in the related art.

The fabrication method of an N-polar GaN transistor structure according to the present embodiment may include the following steps: S1: depositing the buffer layer 170 on one side of a structural substrate 180.

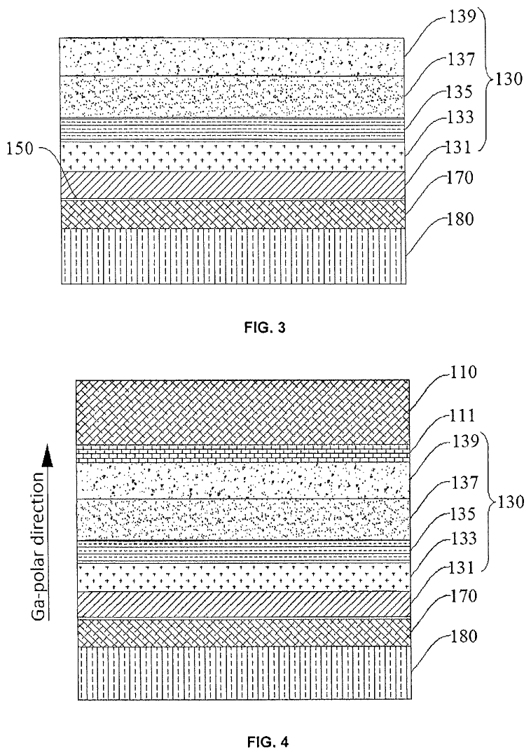

Referring to FIG. 2 in combination, the structural substrate 180 may be made of one or a combination of more of Si, Sapphire, SiC, and GaN, or any other material capable of growing III-nitride. A deposition method of the structural substrate 180 may be chemical vapor deposition (CVD), vapor phase epitaxy (VPE), metal-organic vapor phase epitaxy (MOVPE), low-pressure chemical vapor deposition (LPCVD), plasma-enhanced chemical vapor deposition (PECVD), pulsed laser deposition (PLD), atomic layer epitaxy, molecular beam epitaxy (MBE), sputtering, evaporation, or the like.

In the present embodiment, the structural substrate 180 is preferably made of a Si(111) material, so as to facilitate a substrate stripping in a subsequent process.

In the present embodiment, the buffer layer 170 serves as a transition layer between a subsequent GaN epitaxial structure and the structural substrate 180 during growth, so as to solve problems of lattice mismatch, thermal expansion coefficient mismatch, or the like, between materials of a GaN film and the structural substrate 180. Here, the buffer layer 170 may be made of at least one of GaN, AlN, InAlN, AlGaN, InAlGaN, and other semiconductor materials. Preferably, the buffer layer 170 may be made of at least one of AlGaN and AlN based on the Si(111) material used for the structural substrate 180. S2: depositing an etching-blocking barrier layer 150 on a side of the buffer layer 170 away from the structural substrate 180.

In the present embodiment, the etching-blocking barrier layer 150 is mainly used to play a blocking role in a subsequent etching process, so as to form a natural blocking layer to block an etching. The etching-blocking barrier layer 150 may be preferably made of AlₓGa₁₋ₓN, x is a fraction of Al, and 0<x≤1. Certainly, here, the material of the etching-blocking barrier layer 150 is required to be different from the material of a side of the buffer layer 170 close to the barrier layer, such that the etching-blocking barrier layer 150 may serve as an etching stop layer when the buffer layer 170 is etched, the selected material of the etching-blocking barrier layer 150 is merely used for illustration and not for limitation, and any material capable of achieving the etching stop function here is within the protection scope of the present application.

It should be noted that, in order to prevent the etching-blocking barrier layer 150 from affecting subsequent fabrication of a metal electrode, the etching-blocking barrier layer 150 is thin here. Specifically, the etching-blocking barrier layer 150 has a thickness of at least 1 nm, preferably 2 nm. S3: depositing an epitaxial functional layer 130 of an upside-down N-polar transistor on a side of the etching-blocking barrier layer 150 away from the structural substrate 180.

Referring to FIG. 3 in combination, specifically, the epitaxial functional layer 130 of the upside-down N-polar transistor is deposited on the etching-blocking barrier layer 150 using a conventional deposition method. Here, the epitaxial functional layer 130 may include a channel layer 131, a barrier layer 133, an isolation layer 135, an insulating layer 137, and a p-type doped layer 139 which are deposited sequentially. Meanwhile, in order to guarantee uniformity in the whole structure deposition process, a Ga-polar growth method is adopted in both the buffer layer 170 and the etching-blocking barrier layer 150, a side of the epitaxial functional layer 130 away from the structural substrate 180 is a Ga-polar surface, and a side of the epitaxial functional layer 130 away from a support substrate 110 is an N-polar surface.

It should be noted that, in the present embodiment, the buffer layer 170, the etching-blocking barrier layer 150, the epitaxial functional layer 130, and other epitaxial structures are directly and sequentially grown using the MOVPE or MBE method.

In the present embodiment, Step S3 may specifically include the following sub-steps. S31: depositing the Ga-polar channel layer 131 on the etching-blocking barrier layer 150.

Specifically, the channel layer 131 is configured to provide a channel for a two-dimensional electron gas (2DEG) to move, and made of a material including nitride, for example, at least one of GaN, AlN, InAlN, AlGaN, InAlGaN, and other semiconductor materials, and preferably, the channel layer 131 may be made of GaN or an AlGaN material having a low Al fraction. S32: depositing the Ga-polar barrier layer 133 on the channel layer 131.

Specifically, the barrier layer 133 covers the channel layer 131 and is configured to form a heterojunction with the channel layer 131, and the barrier layer 133 is made of a material including ternary nitride, for example, at least one of AlN, InAlN, AlGaN, InAlGaN, and other semiconductor materials. Here, the barrier layer 133 has a wider energy gap than the channel layer 131 to form the two-dimensional electron gas with a high concentration and high electron mobility at an interface between the barrier layer 133 and the channel layer 131, close to the channel layer 131; for example, when the channel layer 131 is made of GaN, the barrier layer 133 may be made of InAlN, AlGaN, or AlN. S33: depositing the Ga-polar isolation layer 135 on the barrier layer 133.

Specifically, the isolation layer 135 is configured to isolate the barrier layer 133 from the subsequently deposited insulating layer 137, which may be made of an unintentionally doped grown GaN material. S34: depositing the Ga-polar insulating layer 137 on the isolation layer 135.

Specifically, the insulating layer 137 has a high resistance characteristic which may be realized by self-doping of carbon or intentional doping of iron during growth of the GaN material.

It should be noted that, for the N-polar GaN material conventionally grown directly on a substrate, an insulating layer with a high resistance is usually difficult to realize by self-doping of carbon or intentional doping of iron due to the high background electron concentration. S35: depositing the p-type doped layer 139 on the insulating layer 137.

Specifically, the p-type doped layer 139 may be made of conventional p-GaN material, thus improving the longitudinal high-voltage resistance of the device.

It should be noted that, here, the p-type doped layer 139 is an outermost structure of the epitaxial functional layer 130, and in other preferred embodiments, Step S35 may be omitted, such that the p-type doped layer 139 is omitted, and the insulating layer 137 becomes the outermost structure of the epitaxial functional layer 130.

In the present embodiment, after the device is inverted, the p-type doped layer 139 is the outermost structure of the epitaxial functional layer 130, and at this point, the p-type doped layer 139 is exposed outside, thus facilitating activation of annealing after the doping. For example, when made of Mg-doped Ga(Al)N, the p-type doped layer 139 has to be exposed to a high temperature for annealing, so as to realize p-type conduction. If conventionally, the epitaxial functional layer 130 of the N-polar transistor is grown after the N-polar p-type doped layer 139 is grown directly on the substrate, the p-type doped layer 139 is buried under the epitaxial functional layer 130, such that a doping source is difficult to activate by the annealing to realize the p-type conduction.

It should also be noted that, in the present embodiment, in Step S31 to Step S35, the Ga-polar epitaxial layer structures are directly grown using the MOVPE or MBE method, and a Ga-polar direction is from the structural substrate 180 towards the p-type doped layer 139. S4: bonding the support substrate 110 on a side of the epitaxial functional layer 130 away from the structural substrate 180.

Referring to FIG. 4 in combination, specifically, a bonding layer 111 is deposited on the epitaxial functional layer 130, and the support substrate 110 is bonded on the bonding layer 111. That is, the bonding layer 111 is deposited on a side surface of the p-type doped layer 139 away from the structural substrate 180, and the epitaxial functional layer 130 and the support substrate 110 are bonded using a method, such as direct bonding, gluing bonding, or the like. The support substrate 110 may be made of Si, SOI, silicon carbide, diamond, or the like. Meanwhile, the selection of the material of the bonding layer 111 is dependent on a bonding process. For example, when selected to be directly bonded to an SOI substrate, the bonding layer 111 may be made of silicon oxide or silicon nitride.

It should be noted that, here, using the bonding method, bonding to materials with high thermal conductivity (SiC, diamond, or the like) is possible, thereby improving the heat dissipation capability and thermal reliability of the device. Furthermore, other devices, such as a Si-based CMOS device, may be fabricated in advance on the SOI substrate, and in the present embodiment, Si and the SOI substrate may be combined using the bonding method, and other devices, such as a Si-based CMOS device, may be integrated on the SOI substrate, thereby realizing the integration of different devices. S5: removing the structural substrate 180 and exposing the buffer layer 170.

Referring to FIG. 5 in combination, specifically, after fabrication of the support substrate 110 is completed, the device is inverted and the structural substrate 180 is stripped. An N-polar direction at this point is from the support substrate 110 towards the etching-blocking barrier layer 150. By stripping the structural substrate 180, the N-polar surface of the buffer layer 170 is exposed, and the stripping method of the structural substrate 180 is dependent on a selected material; for example, if made of Si(111), the structural substrate 180 may be removed directly using a chemical corrosion method. Certainly, other conventional substrate stripping methods, such as laser stripping, may be used here. S6: removing the buffer layer 170 and exposing the etching-blocking barrier layer 150.

Referring to FIG. 6 in combination, specifically, the buffer layer 170 is etched away first, thereby exposing the etching-blocking barrier layer, and obtaining an N-polar GaN-based HEMT device structure; here, the etching-blocking barrier layer 150 may realize self-termination of the etching process.

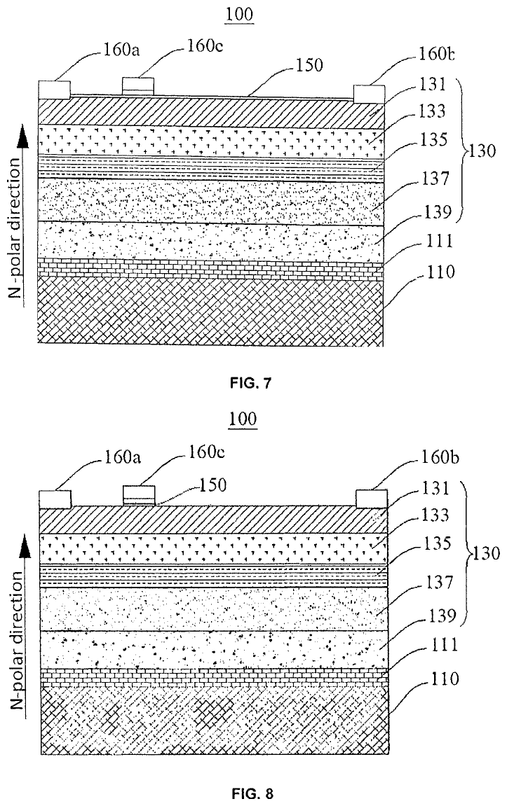

It should be noted that, here, the etching-blocking barrier layer 150 may be removed or partially removed, or may not be removed. The etching-blocking barrier layer 150 is partially removed as shown in FIG. 8. When the etching-blocking barrier layer 150 is partially removed, only a gate electrode region is reserved. S7: manufacturing a source electrode 160a, a drain electrode 160b, and a gate electrode 160c on a side of the epitaxial functional layer 130 away from the support substrate 110.

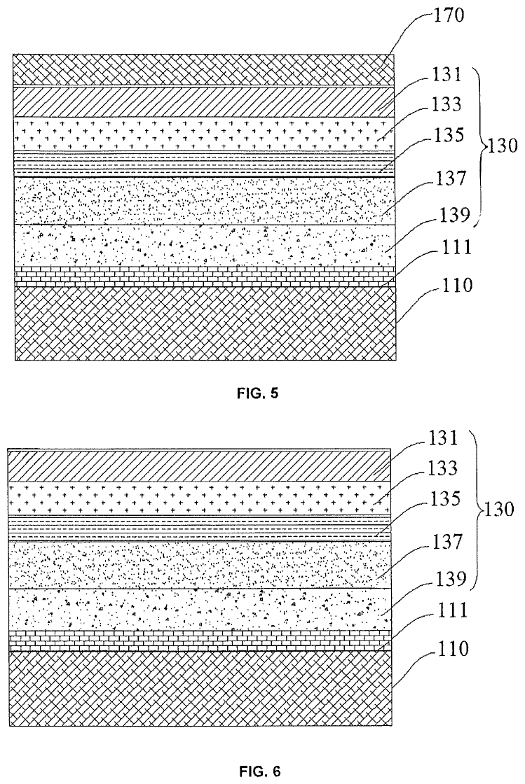

Referring to FIG. 7 in combination, specifically, after the etching-blocking barrier layer 150 is removed, the source electrode 160a, the drain electrode 160b, and the gate electrode 160c are manufactured on a side surface of the channel layer 131 away from the support substrate 110 according to a conventional process, wherein the gate electrode 160c is located between the source electrode 160a and the drain electrode 160b. When the etching-blocking barrier layer 150 is not removed, the source electrode 160a, the drain electrode 160b, and the gate electrode 160c are manufactured on a surface of the etching-blocking barrier layer 150. When the etching-blocking barrier layer 150 is partially removed, the gate electrode 160c is manufactured on the surface of the etching-blocking barrier layer 150, and the source electrode 160a and the drain electrode 160b are manufactured on the surface of the channel layer 131.

It should be noted that after the metal electrode is manufactured, an N-polar GaN-based HEMT structure is obtained, and an enhanced N-polar GaN-based HEMT structure or a depletion N-polar GaN-based HEMT structure may be formed according to a manufacturing difference of the metal electrode. During the formation of the depletion N-polar GaN-based HEMT structure, the etching-blocking barrier layer 150 is preferably required to be removed; during the formation of the enhanced N-polar GaN-based HEMT structure, the etching-blocking barrier layer 150 is preferably required to be partially removed, only the gate electrode region is reserved, and thicknesses and Al fractions of the channel layer 131 and the barrier layer 133 are adjusted correspondingly to deplete the two-dimensional electron gas at the interface between the channel layer 131 and the barrier layer 133 below the gate electrode 160c.

It should also be noted that when not removed here, the etching-blocking barrier layer 150 may also serve as a barrier layer for reducing device electric leakage during the manufacture of the source electrode 160a, the drain electrode 160b, and the gate electrode 160c.

With continued reference to FIG. 7, the present embodiment further provides a semiconductor structure 100 which is manufactured using the aforementioned fabrication method of an N-polar GaN transistor structure, and the semiconductor structure 100 may include an etching-blocking barrier layer 150, an epitaxial functional layer 130 located on one side of the etching-blocking barrier layer 150, a support substrate 110 located on a Ga-polar surface of the epitaxial functional layer 130, and a source electrode 160a, a drain electrode 160b, and a gate electrode 160c located on an N-polar surface of the epitaxial functional layer 130, with a side of the epitaxial functional layer 130 close to the etching-blocking barrier layer 150 being the N-polar surface, and a side of the epitaxial functional layer 130 away from the etching-blocking barrier layer 150 being the Ga-polar surface.

Specifically, the semiconductor structure 100 according to the present embodiment is an N-polar GaN-based HEMT structure in which an N-polar direction is towards the epitaxial functional layer 130 from the support substrate 110.

In the present embodiment, the epitaxial functional layer 130 includes a channel layer 131, a barrier layer 133, an isolation layer 135, an insulating layer 137, and a p-type doped layer 139, wherein the p-type doped layer 139 is bonded on the support substrate 110, and a bonding layer 111 is further formed between the p-type doped layer 139 and the support substrate 110 to realize a bonding. The insulating layer 137 is located on a side of the p-type doped layer 139 away from the support substrate 110, the isolation layer 135 is located on a side of the insulating layer 137 away from the support substrate 110, the barrier layer 133 is located on a side of the isolation layer 135 away from the support substrate 110, and the channel layer 131 is located on a side of the barrier layer 133 away from the support substrate 110. Furthermore, reference may be made to the preceding description for a specific deposition method of the epitaxial functional layer 130.

In other embodiments, the etching-blocking barrier layer 150 may also be removed; that is, the semiconductor structure 100 includes the epitaxial functional layer 130, the support substrate 110 located on the Ga-polar surface of the epitaxial functional layer 130, and the source electrode 160a, the drain electrode 160b and the gate electrode 160c located on the N-polar surface of the epitaxial functional layer 130. That is, the source electrode 160a, the drain electrode 160b, and the gate electrode 160c may be directly manufactured on a surface of the channel layer 131.

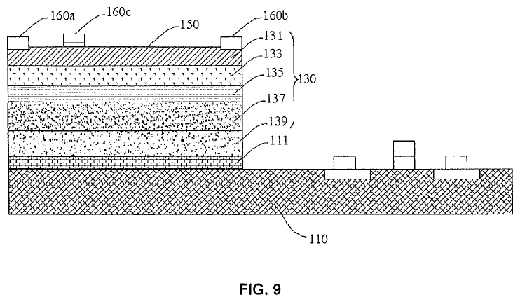

Referring to FIG. 9, in the present embodiment, the epitaxial functional layer 130 is bonded on the support substrate 110, and meanwhile a Si-based CMOS device or a gate electrode 160c driving circuit is integrated on the support substrate 110, thereby achieving integrating different devices.

In summary, the present embodiment provides the fabrication method of an N-polar GaN transistor structure and the semiconductor structure 100, the Ga-polar epitaxial functional layer 130 is deposited, the support substrate 110 is bonded to the epitaxial functional layer 130, the structural substrate 180 and the buffer layer 170 are removed after the epitaxial structure is inverted, and the source electrode 160a, the drain electrode 160b and the gate electrode 160c are manufactured on the side of the exposed epitaxial functional layer 130 away from the support substrate 110, so as to form the semiconductor device. Since the epitaxial functional layer 130 is formed by Ga-polar growth, and a comprehensive quality of the directly grown Ga-polar GaN material is usually superior to that of the directly grown N-polar GaN material, the GaN material with a smooth surface, a low impurity concentration and a high crystal quality may be obtained by directly growing the Ga-polar epitaxial functional layer 130; since the N-polar direction is opposite to the Ga-polar direction of the semiconductor structure 100, the epitaxial functional layer 130 on the N-polar surface is obtained by removing the structural substrate 180 and the buffer layer 170 after inversion, thus obtaining an N-polar epitaxial structure, and manufacturing the N-polar semiconductor device. In the present embodiment, due to the adoption of the method in which the Ga-polar epitaxial structure is grown first, the bonding is then performed, and the substrate and the buffer layer 170 are removed, the N-polar semiconductor device has a better material quality and a device performance.

The foregoing descriptions are merely specific embodiments of the present application but are not intended to limit the protection scope of the present application. Any variation or replacement readily figured out by a person skilled in the art within the technical scope disclosed in the present application shall fall within the protection scope of the present application. Therefore, the protection scope of the present application shall be subject to the protection scope of the claims.

### INDUSTRIAL APPLICABILITY

The present application provides the fabrication method of an N-polar GaN transistor structure and the semiconductor structure, and relates to the field of semiconductor technologies; the Ga-polar epitaxial functional layer is deposited, the support substrate is bonded to the epitaxial functional layer, the structural substrate and the buffer layer are removed after the epitaxial structure is inverted, and the source electrode, the drain electrode and the gate electrode are manufactured on the side of the exposed epitaxial functional layer away from the support substrate, so as to form the N-polar GaN transistor structure. Here, the epitaxial structure of the N-polar GaN transistor is obtained by vertically inverting the directly grown Ga-polar epitaxial layer, and has a higher material quality than the N-polar material which is directly grown epitaxially, such that the high-resistance GaN insulating layer and the steep-interface heterojunction may be obtained, thus improving a high-voltage resistance of the N-polar GaN transistor, reducing a conduction loss of the device, and improving an overall performance of the device.

The fabrication method of an N-polar GaN transistor structure according to the present application may be reproduced utilizing an existing semiconductor manufacturing technology, and the N-polar GaN semiconductor structure according to the present application may be applied to various industrial fields including a radio frequency power amplification device required in 5G communication, a high-power high-frequency switch device required in power control and management, a gas sensing device, or the like.

1. A fabrication method of an N-polar GaN transistor structure, comprising steps of:
depositing a buffer layer on one side of a structural substrate;
depositing an etching-blocking barrier layer on a side of the buffer layer away from the structural substrate;
depositing an epitaxial functional layer of an upside-down N-polar transistor on a side of the etching-blocking barrier layer away from the structural substrate, such that a side of the epitaxial functional layer away from the structural substrate is a Ga-polar surface;
forming by bonding a support substrate on the side of the epitaxial functional layer away from the structural substrate;
removing the structural substrate to make the buffer layer exposed;
removing the buffer layer to make the etching-blocking barrier layer exposed; and
manufacturing a source electrode, a drain electrode and a gate electrode on a side of the epitaxial functional layer away from the support substrate, so as to form an N-polar GaN transistor.

2. The fabrication method of an N-polar GaN transistor structure according to claim 1, wherein after the step of removing the buffer layer to make the etching-blocking barrier layer exposed, the fabrication method further comprises:
removing the etching-blocking barrier layer to make the epitaxial functional layer exposed.

3. The fabrication method of an N-polar GaN transistor structure according to claim 1, wherein the step of depositing an epitaxial functional layer of an upside-down N-polar transistor on a side of the etching-blocking barrier layer away from the structural substrate comprises steps of:
depositing a Ga-polar channel layer on the etching-blocking barrier layer;
depositing a Ga-polar barrier layer on the channel layer;
depositing a Ga-polar isolation layer on the barrier layer; and
depositing a Ga-polar insulating layer on the isolation layer.

4. The fabrication method of an N-polar GaN transistor structure according to claim 3, wherein the channel layer is made of at least one of GaN, AlN, InAlN, AlGaN and InAlGaN; and the barrier layer is made of at least one of AlN, InAlN, AlGaN, InAlGaN and AlScN, wherein the bandgap of the barrier layer is greater than the bandgap of the channel layer, and a two-dimensional electron gas with a high concentration and a high electron mobility is formed on an interface, at a side close to the channel layer, between the barrier layer and the channel layer.

5. The fabrication method of an N-polar GaN transistor structure according to claim 3, wherein after the step of depositing an insulating layer on the isolation layer, the fabrication method further comprises:
depositing a p-type doped layer on the insulating layer, wherein the p-type doped layer is made of a p-GaN material.

6. The fabrication method of an N-polar GaN transistor structure according to claim 1, wherein a bonding medium is deposited on the side of the epitaxial functional layer away from the structural substrate, and the epitaxial functional layer and the support substrate are bonded by using a method of direct bonding or gluing bonding.

7. The fabrication method of an N-polar GaN transistor structure according to claim 1, wherein the etching-blocking barrier layer is made of AlₓGa₁₋ₓN, wherein x is a fraction of Al, and 0<x≤1; and a fraction of Al in the etching-blocking barrier layer is higher than a fraction of Al in the channel layer.

8. The fabrication method of an N-polar GaN transistor structure according to claim 7, wherein the etching-blocking barrier layer has a thickness of at least 1 nm.

9. A semiconductor structure, manufactured using the fabrication method of an N-polar GaN transistor structure according to claim 1, comprising:
an etching-blocking barrier layer;
an epitaxial functional layer, located on one side of the etching-blocking barrier layer, wherein a side of the epitaxial functional layer close to the etching-blocking barrier layer is an N-polar surface, and a side of the epitaxial functional layer away from the etching-blocking barrier layer is a Ga-polar surface;
a support substrate, located on the Ga-polar surface of the epitaxial functional layer; and
a source electrode, a drain electrode and a gate electrode, located on the N-polar surface of the epitaxial functional layer,
wherein the epitaxial functional layer comprises a channel layer deposited on the etching-blocking barrier layer, a barrier layer deposited on the channel layer, an isolation layer deposited on the barrier layer, and an insulating layer deposited on the isolation layer.

10. The semiconductor structure according to claim 9, wherein the epitaxial functional layer further comprises a p-type doped layer located on the insulating layer.

11. The semiconductor structure according to claim 9, wherein regions of the etching-blocking barrier layer on both sides of the gate electrode are removed partially or completely.

12. The semiconductor structure according to claim 9, wherein the gate electrode is manufactured on the etching-blocking barrier layer, and the source electrode and the drain electrode are manufactured on the channel layer on both sides of the gate electrode.

13. The fabrication method of an N-polar GaN transistor structure according to claim 2, wherein the step of depositing an epitaxial functional layer of an upside-down N-polar transistor on a side of the etching-blocking barrier layer away from the structural substrate comprises steps of:
depositing a Ga-polar channel layer on the etching-blocking barrier layer;
depositing a Ga-polar barrier layer on the channel layer;
depositing a Ga-polar isolation layer on the barrier layer; and
depositing a Ga-polar insulating layer on the isolation layer.

14. The fabrication method of an N-polar GaN transistor structure according to claim 4, wherein after the step of depositing an insulating layer on the isolation layer, the fabrication method further comprises:
depositing a p-type doped layer on the insulating layer, wherein the p-type doped layer is made of a p-GaN material.

15. The fabrication method of an N-polar GaN transistor structure according to claim 2, wherein a bonding medium is deposited on the side of the epitaxial functional layer away from the structural substrate, and the epitaxial functional layer and the support substrate are bonded by using a method of direct bonding or gluing bonding.

16. The fabrication method of an N-polar GaN transistor structure according to claim 3, wherein a bonding medium is deposited on the side of the epitaxial functional layer away from the structural substrate, and the epitaxial functional layer and the support substrate are bonded by using a method of direct bonding or gluing bonding.

17. The fabrication method of an N-polar GaN transistor structure according to claim 4, wherein a bonding medium is deposited on the side of the epitaxial functional layer away from the structural substrate, and the epitaxial functional layer and the support substrate are bonded by using a method of direct bonding or gluing bonding.

18. The fabrication method of an N-polar GaN transistor structure according to claim 2, wherein the etching-blocking barrier layer is made of AlₓGa₁₋ₓN, wherein x is a fraction of Al, and 0<x≤1; and a fraction of Al in the etching-blocking barrier layer is higher than a fraction of Al in the channel layer.

19. The fabrication method of an N-polar GaN transistor structure according to claim 3, wherein the etching-blocking barrier layer is made of AlₓGa₁₋ₓN, wherein x is a fraction of Al, and 0<x≤1; and a fraction of Al in the etching-blocking barrier layer is higher than a fraction of Al in the channel layer.

20. The semiconductor structure according to claim 11, wherein the gate electrode is manufactured on the etching-blocking barrier layer, and the source electrode and the drain electrode are manufactured on the channel layer on both sides of the gate electrode.
